(19) United States
(12) Patent Application Publication
(10) Pub. No.: US 2014/0272291 A1
(43) Pub. Date: Sep. 18, 2014

(54) FABRICATION METHOD FOR HYDROPHILIC ALUMINUM SURFACE AND HYDROPHILIC ALUMINUM SURFACE BODY

(71) Applicant: KOREA INSTITUTE OF SCIENCE AND TECHNOLOGY, SEOUL (KR)

(72) Inventors: Myoung Woon MOON, Seoul (KR); Seong Jin KIM, Seoul (KR); Heon Ju LEE, Gyeonggi-do (KR); Eu Sun YU, Seoul (KR); Tae Jun KO, Seoul (KR); Kyu Hwan OH, Seoul (KR); Kwang Ryeol LEE, Seoul (KR)

(73) Assignee: KOREA INSTITUTE OF SCIENCE AND TECHNOLOGY, SEOUL (KR)

(21) Appl. No.: 14/204,283

(22) Filed: Mar. 11, 2014

(30) Foreign Application Priority Data
Mar. 14, 2013 (KR) 10-2013-0027452

(51) Int. Cl. C23C 22/05; C23C 16/505; C23C 14/34; C23C 14/48; C23C 14/22

(52) U.S. Cl. CPC C23C 22/05; C23C 14/48; C23C 14/221; C23C 14/34; C23C 16/505; B82Y 30/00
USPC 428/141; 427/255.21; 427/255.19; 427/569; 427/528; 204/192.12; 204/192.11; 977/832; 977/891

(57) ABSTRACT

A method for fabricating a hydrophilic aluminum surface includes: an activation step of preparing doped aluminum having an activated surface through doping treatment on a part or whole of an aluminum surface with applying reactive gas thereto; and a structure forming step of preparing a hydrophilic aluminum surface through oxidizing treatment on the doped aluminum to have nano-patterns comprising nano-protrusion structures on the aluminum surface. Hydrophobic aluminum can be fabricated into artificially hydrophilic or super-hydrophilic aluminum, and the hydrophilic aluminum surface body that does not have an aging effect and has long-lasting hydrophilicity can be provided.

### CROSS-REFERENCE TO RELATED APPLICATION

Pursuant to 35 U.S.C. §119(a), this application claims the benefit of earlier filing date and right of priority to Korean Application No. 10-2013-0027452, filed on Mar. 14, 2013, the contents of which is incorporated by reference herein in its entirety.

### BACKGROUND OF THE INVENTION

1. Field of the Disclosure

The present disclosure relates to a fabrication method for an aluminum surface having an improved hydrophilicity and a hydrophilic aluminum surface body, and more particularly, to a method for artificially fabricating a hydrophilic or super-hydrophilic aluminum surface having a considerably low wettability and a small contact angle of a fluid such as deionized water, and a surface body thereof.

2. Background of the Disclosure

The development of a material used for dehumidification, removing moisture from the air in an environment having high humidity and high temperature, is very critical to reduce energy and to enhance dehumidification capability. In particular, moisture in both industrial sites and households is one of the crucial factors to bring mechanical troubles of components and equipment. However, a current dehumidification system uses Freon gas which causes harm to an environment, or an absorbent required to be heated at a high temperature. And, this increases cost of a product and contaminates an environment.

In order to reduce energy consumption and enhance dehumidification efficiency, it is important to treat a surface of a material such as aluminum, which has used in a surface of a heat exchanger or a dehumidifier, to have hydrophilic properties. The surface having hydrophilic properties allows moisture to easily cling thereto. Also, the development of a surface material having durability of the hydrophilic properties is highlighted.

A hydrophilic surface or a super-hydrophilic surface having good affinity with pure water has been continuously studied for the purpose of harvesting water, anti-fog, or anti-bacteria, for the purpose of growing cells, or for the purpose of enhancing characteristics of bonding with a different material by modifying the characteristics of a material surface.

As a method of preparing a hydrophilic or super-hydrophilic surface on a surface of a material, wet etching, UV treatment, or a plasma ion treatment, and the like, are used. In particular, it has been known that a hydrophilic or super-hydrophilic can be obtained by increasing roughness of a surface and adjusting chemical properties of a surface by using a material having hydrophilic property.

Attempts have been made to implement hydrophilic characteristics on a surface of various materials and thin film, but hydrophilic properties of surface is easily gone (so-called “aging effect.”) The reason is that surface energy of a hydrophilic surface is relatively high, so it tends to be easily combined with fine particles such as water molecules and hydrocarbon in the air, for reducing its surface energy. Thus, when such bonding is made, surface energy is lowered to lose hydrophilicity. For this reason, most hydrophilic or super-hydrophilic treatment based on the conventional method loses the hydrophilic property within a few hours or a few days. Thus, research into maintaining hydrophilic or super-hydrophilic characteristics for a long period of time has been variously conducted.

It is known that a surface treated with oxygen or nitrogen plasma, or the like, can increase hydrophilicity, but it is thermodynamically unstable to bring about an aging effect due to a property to return hydrophobicity. [Roy et al, Diamond and Related Materials, 16 (2007), 1732-1738].

A technique of preventing an aging effect may be used for coating technique of restraining fogging of the mirror of a bathroom, glasses put on in the cold winter, vehicle glass, and the like, as well as being applied to a field required for application to living bodies. Also, the technique of preventing an aging effect is possible to be applied to a various fields such as a technique of increasing heat transfer efficiency of a surface of an evaporator in a refrigerator, or a technique of using a fan of a heat exchanger controlling humidity as a surface of a dehumidifier in an air-conditioner. In addition, when applied to an internal pipe of piping, the technique may be applied to special sanitary plumbing, or the like such as restraining bacterial multiplication and reducing flow resistance.

Recently, developed methods for forming an super-hydrophilic surface comprises a method for fabricating a porous material having a nano-scale by depositing TiO₂ coating, a method for forming a hydrophilic surface by mixing nano-scale particles such as TiO₂ particles and SiO₂ particles in an appropriate ratio, and the like. [F C Cebeci, Langmuir 22 (2006), 2856]. However, a surface material prepared by these methods are disadvantageous in that it is not available for a large area or mass-production, and adhesion strength between a coated material and a base material, and the like, may also be problematic.

In case of a heat-exchanger (evaporator), a refrigerator, or an air-conditioner, performance or efficiency of a system is proportional to a heat transfer area of the heat-exchanger. Thus, various types of fins are attached to increase a heat transfer area. The crucial factor of degrading performance and efficiency of a refrigerator or a dehumidification system is dew condensation (frost) formed on a surface of an evaporator. That is, condensed droplets are frozen to reduce a heat exchange area, or droplets between fins adhere to block a flow path of an air side, degrading a heat-exchange flow rate and increasing a blower load. In addition, since heat-exchanging is not smoothly performed, the flow path of the air side is clogged due to continuous dew condensation on an outer surface of the evaporator, the blower is overloaded to be broken, and in the worst case scenario, the system is stopped.

In this case, additional heat is supplied from the outside to perform defrosting or a refrigerant is periodically inversely circulated to heat the evaporator to perform defrosting, which degrades system efficiency due to the additional energy supply. Thus, a method of treating an outer surface of an evaporator to have hydrophilicity to restrain a generation of droplet on a surface of a heat exchanger, and constantly forming a uniform thin water film to maintain a constant heat exchange performance has been researched as a solution [C. C. Wang, International Journal of Heat and MassTransfer 41 (1998), 3109]. Based on a principle of the refrigerator or the air-conditioner, even in case of an evaporator included in a dehumidifier which does not use a liquid type dehumidifier and collecting moisture according to condensation occurring in a surface thereof, when a surface of the evaporator is treated to have hydrophilicity, performance and efficiency of the dehumidifier can be enhanced. [G-R Kim, Experimental Thermal and Fluid Science 27 (2002), 1-10]. However, durability of the surface treatment for hydrophilicity is controversial all the time, and a hydrophilicity surface treatment technique, which is environmentally friendly and incurs low treatment costs, is required.

Thus, the present invention proposes a surface treatment method providing enhanced durability in comparison to any other existing surface treatment techniques, and treating a surface through relatively simple equipment regardless of a shape through environmentally friendly process.

### SUMMARY OF THE INVENTION

Therefore, an aspect of the detailed description is to provide a method for fabricating hydrophilic aluminum surface, and a hydrophilic surface body, and in this case, the aluminum surface body has hydrophilicity having a small pure water contact angle, and an aluminum material having lasting hydrophilic characteristics are provided.

To achieve these and other advantages and in accordance with the purpose of this specification, as embodied and broadly described herein, a method for fabricating a hydrophilic aluminum surface includes the steps of: an activation step of preparing doped aluminum having an activated surface through doping treatment on a part or whole an aluminum surface with applying a reactive gas thereto; and a structure forming step of preparing a hydrophilic aluminum surface through oxidizing treatment on the doped aluminum to have nano-patterns comprising nano-protrusion structures on the aluminum surface.

The doping treatment may be performed through an atmospheric plasma treatment method, a plasma chemical vapor deposition method, an ion beam deposition method, a plasma ion immersion implantation method, or a sputter process.

The doped aluminum may be doped with one element selected from the group consisting of fluorine (F), chlorine (Cl), or a combination thereof.

The reactive gas may comprise any one selected from the group consisting of CHF₃, C₂F₆, C₂Cl₂F₄, C₃Fₐ, C₄F₈, SF₆, and combinations thereof.

The doping treatment may be performed under the conditions in which pressure ranges from 2 Pa to 10 Pa and power ranges from 100 W to 300 W.

The doping treatment may be performed through a plasma-assisted chemical vapor deposition (PACVD) using radio frequency (RF) power.

The oxidization of the structure forming step may be performed by contacting the activated surface of the doped aluminum with a reaction solution comprising water or steam thereof.

The oxidization of the structure forming step may be performed by contacting the activated surface of the doped aluminum with the reaction solution having a temperature ranging from 70° C. to 90° C. or steam thereof.

The nano-protrusion structures may comprise needle-shaped, plate-shaped (nano-flake), or dot-shaped nano-protrusions, and nano-protrusions of the nano-protrusion structures may contain any one selected from the group consisting of boehmite [AlO(OH)], aluminum oxide (Al₂O₃), and a combination thereof.

The hydrophilic aluminum surface may have super-hydrophilicity in which a pure water contact angle is equal to or less than 10 degrees.

To achieve these and other advantages and in accordance with the purpose of this specification, as embodied and broadly described herein, an aluminum surface body including nano-patterns having nano-protrusion structures formed on a part or whole of an aluminum surface, wherein the nano-protrusion structures include needle-shaped, plate-shaped, or dot-shaped nano-protrusions. The needle-shaped or plate-shaped nano-protrusions have a height ranging from 10 nm to 100 nm. The nano-protrusions may include any one selected from the group consisting of boehmite [AlO(OH)], aluminum oxide (Al₂O₃), and a combination thereof.

The hydrophilic aluminum surface may have super-hydrophilicity in which a pure water contact angle is equal to or less than 10 degrees.

To achieve these and other advantages and in accordance with the purpose of this specification, as embodied and broadly described herein, a dehumidifier includes the foregoing hydrophilic aluminum surface body.

To achieve these and other advantages and in accordance with the purpose of this specification, as embodied and broadly described herein, a water collector includes the foregoing hydrophilic aluminum surface body.

Hereinafter, the present invention will be described in detail.

The present invention relates to a method for fabricating a hydrophilic aluminum material having a surface which has a small pure water contact angle wherein the small contact angle has durability without being affected by an aging effect, and an aluminum surface body.

In an embodiment of the present invention, aluminum refers to a material or an article fabricated to include aluminum regardless of a shape, a thickness, whether it is combined with a different material, and not limited to a material made of pure aluminum.

A method for fabricating a hydrophilic aluminum surface comprises an activation step and a structure forming step.

The activation step includes a process of preparing a doped aluminum having an activated surface through doping treatment on a part or whole of an aluminum surface with applying a reactive gas thereto.

The doped aluminum may be doped with one element selected from the group consisting of fluorine (F), chlorine (Cl), or a combination thereof. After the surface of the aluminum is activated, needle-shaped, plate-shaped, or dot-shaped nano-protrusion structures may be formed through a surface oxidation in the structure forming step.

As the doping treatment, any process may be applied as long as it can prepare a doped aluminum by doping the foregoing elements on a surface of aluminum. Preferably, plasma, ion-beam, or a sputter process applying a reactive gas may be used. As the plasma treatment, an atmospheric plasma deposition method, a plasma chemical deposition method, an ion-beam deposition method, a plasma injection method, or the like, may be used.

For the doping treatment, PACVD may be applied. PACVD is a method of converting a precursor desired to be doped into a plasma form and depositing or doping the same on a surface of a substrate such as aluminum. The application of PACVD may obtain advantageous effects such that process parameters may be easily controlled during deposition or doping and harmfulness may be significantly reduced.

The doping treatment may be performed under the conditions in which pressure ranges from 2 Pa to 10 Pa and power ranges from 100 W to 300 W. When doping treatment is performed under the foregoing pressure and power conditions, coating process parameters can be accurately controlled and a surface activity process may be stably performed.

The reactive gas may be one selected from the group consisting of CHF₃, C₂F₆, C₂Cl₂F₄, C₃F₈, C₄F₈, SF₆, and combinations thereof. In the case of using the reactive gas for the doping treatment, the surface of aluminum may be further effectively doped.

The structure forming step may include oxidizing treatment on the doped aluminum to have nano-patterns on a surface of the aluminum. The nano-patterns may include nano-protrusion structures, the nano-protrusion structures may be structures including a plurality of nano-protrusions, and the nano-protrusions may have a needle-shape, a plate shape, or dot-shape

The oxidization of the structure forming step may be performed by contacting the activated surface of the doped-aluminum with a reaction solution having a temperature ranging from 70° C. to 90° C. and comprising water or steam thereof. The water may include distilled water, deionized water, and a combination thereof. The reaction solution may be made of water or may be made of salt including acid and chlorine (Cl) with water, and a combination thereof. Salt including chlorine (Cl) may be, for example, sodium chloride.

A surface of aluminum after undergoing the activation step may be easily oxidized through doping. When the surface of aluminum on which oxidation has been accelerated electrochemically through doping comes into contact with a reaction solution including water or steam thereof, nano-patterns as nano-protrusion structures including needle-shaped nano-protrusions are formed thereon. As the surface of the doped aluminum comes into contact with water included in the reaction solution or steam thereof, oxidation takes place, and as the needle-shaped nano-protrusions are grown, nano-patterns having nano-protrusion structures comprising dense plate shaped nano-protrusions (nano-flake) may be formed.

In particular, when the structure forming step is performed within a reaction solution including water, aluminum oxide formed on the surface of aluminum is attacked by bubbles existing in the reaction solution, accelerating formation of nano-protrusion structure.

The reaction solution or steam thereof may have a temperature ranging from 70° C. to 90° C.

The nano-protrusion structures may include any one selected from the group consisting of boehmite [AlO(OH)], aluminum oxide (Al₂O₃), and a combination thereof, or may be formed of any one selected from the group consisting of boehmite [AlO(OH)], aluminum oxide (Al₂O₃), and a combination thereof.

When the nano-protrusions have a needle shape, a length direction thereof is substantially perpendicular to the surface of aluminum, one end thereof in the length direction is chemically bonded with the surface of aluminum and the other end forms the hydrophilized surface of aluminum and is in contact with air. Also, when the nano-protrusion structures are nano-flake, one end thereof in a height direction substantially perpendicular to the surface of aluminum is chemically bonded with aluminum, and the other end forms the hydrophilized surface of the aluminum surface body and is in contact with air. The shape of the nano-protrusion structures as nano-flake is similar to a leaf or petal. Also, end portions of the plate-shaped nano-protrusion structures may have a sawtooth-like shape.

When the surface of aluminum includes nano-patterns comprising nano-protrusion structures, a hydrophobic surface of aluminum are changed to hydrophilic surface due to fine nano-patterns. Also, the nano-patterns have excellent durability, are chemically stable, and long-lasting hydrophilicity.

When the nano-protrusions have a needle shape, a height thereof may range from 10 nm to 100 nm, and when the nano-protrusions have a plate shape, a height thereof may range from 10 nm to 100 nm and a width thereof may range from 10 nm to 100 nm.

Aluminum treated through the method for fabricating a hydrophilic aluminum surface may have a hydrophilic surface in which a pure water contact angle is equal to or less than 20 degrees or may have a super-hydrophilic surface in which a pure water contact angle is equal to or less than 10 degrees.

According to the method for fabricating a hydrophilic aluminum surface, a hydrophobic aluminum may be fabricated into artificially hydrophilic or super-hydrophilic aluminum without forming a coating film obtained by coating an extra additive such as hydrophilic polymer, or the like. The fabricated hydrophilic or super-hydrophilic aluminum may have enhanced dehumidification function and may be utilized for the purpose of collecting water, preventing fog (anti-fog), self-cleaning, anti-bacteria, or growing cells. Also, the hydrophilic aluminum fabricated according to the fabrication method does not have an aging effect, has long-lasting hydrophilicity, and has the hydrophilic surface obtained without using a hydrophilic coating agent. In addition, the method for fabricating a hydrophilic aluminum surface is applicable to large aluminum, is available for a process in a low vacuum state or in a normal pressure state so as to be appropriate for mass-production, and capable of providing hydrophilic aluminum in an environmentally-friendly manner by minimizing the use of a toxic agent such as an acidic solution.

A hydrophilic aluminum surface body according to another embodiment of the present invention is aluminum including nano-patterns having nano-protrusion structures formed on a portion or the entirety of a surface thereof. The nano-protrusion structures may include nano-protrusions comprising a needle shape or a plate shape having a height ranging from 10 nm to 100 nm. The nano-protrusions may include any one selected from the group consisting of boehmite [AlO(OH)], aluminum oxide (Al₂O₃), and a combination thereof, and may be made of the same.

When the nano-protrusion structure has a plate shape, a width thereof may range from 10 nm to 100 nm. Also, the hydrophilic aluminum surface body may have hydrophilicity in which a pure water contact angle is equal to or less than 20 degrees or may have super-hydrophilicity in which a pure water contact angle is equal to or less than 10 degrees.

The hydrophilic aluminum surface body is hydrophilized through a technique of controlling fine structures on the aluminum surface thereof, and thus, it can maintain hydrophilicity or super-hydrophilicity for a remarkable long period of time, relative to simple coating or surface activation treatment. In addition, since hydrophilicity is provided by the nano-patterns chemically bonded with the surface of aluminum, and since the nano-patterns are stable in terms of energy, the hydrophilic aluminum surface body has excellent durability.

A product according to another embodiment of the present invention includes the foregoing hydrophilic aluminum surface body. The product may be a product in which the hydrophilic aluminum surface of applied to a part or whole of components thereof. The product may include an industrial or household dehumidifier, a sanitary pipe, a mirror or glass that does not steam up, various heat-exchangers such as an air-conditioner, a refrigerator, a freezer.

According to the method for fabricating hydrophilic aluminum surface, since a contact angle is small, hydrophobic aluminum may be fabricated into artificially hydrophilic or super-hydrophilic aluminum, and the hydrophilic aluminum surface body that does not have an aging effect and has long-lasting hydrophilicity can be provided. Also, excellent hydrophilicity can be provided to the aluminum surface without using a hydrophilic coating agent. The method for fabricating a hydrophilic aluminum surface is a method which is applicable to large aluminum, is available for a process in a low vacuum state or in a normal pressure state so as to be appropriate for mass-production, and is environmentally-friendly by minimizing the use of a toxic agent such as an acidic solution.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the detailed description.

### BRIEF DESCRIPTION OF THE DRAWINGS

The accompanying drawings, which are included to provide a further understanding of the invention and are incorporated in and constitute a part of this specification, illustrate exemplary examples and together with the description serve to explain the principles of the invention.

In the drawings:

FIG. 1 is a schematic view illustrating a method for fabricating a hydrophilic aluminum surface according to an embodiment of the present invention.

FIG. 2 is a photograph of a contact angle on a general aluminum surface which was not undergone a hydrophilic aluminum surface treatment (top), and a photograph of a contact angle on an aluminum surface which was undergone a hydrophilic aluminum surface treatment according to the present invention (bottom).

FIG. 3 is an electron microscope photograph of a general aluminum (purity Al=99.9%) surface corresponding to the top case of FIG. 2.

FIG. 4 is an electron microscope photograph of an aluminum surface with nano-protrusion structures of a plate shape (nano-flake form) corresponding to the bottom case of FIG. 2 by magnifying it.

FIG. 5 is an electron microscope photograph in which petal structures are observed by magnifying the photograph of FIG. 3.

FIG. 6 is an electron microscope photograph of an aluminum surface having nano-protrusion structures fabricated by differentiating plasma doping time and magnifying it according to an embodiment of the present invention.

FIG. 7 shows results of an XPS component analysis indicating that components of the nano-protrusion structures are an aluminum oxide layer (boehmite).

FIG. 8 is a graph showing a change in a pure water contact angle measured on an aluminum surface by using Example 3 in which the aluminum surface was activated by using a plasma treatment under the indicated pressure and voltage conditions and then a structure forming step was performed thereon.

FIGS. 9 and 10 are graphs showing a change in a pure water contact angle over time by keeping a hydrophilic aluminum surface in the air. In FIG. 9, ▪ indicates results of a measurement of a change in a contact angle of aluminum according to comparative example 1, and indicates results of a measurement of a change in a contact angle of hydrophilic aluminum treated according to an example of the present invention. Also, in FIG. 10, indicates results of a measurement of a change in a contact angle on an aluminum surface treated with boiling water without activation, and ▪ indicates results of a change in a contact angle of hydrophilic aluminum treated according to an example of the present invention over time.

### DETAILED DESCRIPTION OF THE INVENTION

Description will now be given in detail of the exemplary examples, with reference to the accompanying drawings. For the sake of brief description with reference to the drawings, the same or equivalent components will be provided with the same reference numbers, and description thereof will not be repeated.

Hereinafter, examples will be described in detail with reference to the accompanying drawings such that they can be easily practiced by those skilled in the art to which the present invention pertains. However, the present invention may be implemented in various forms and not limited to the examples disclosed hereinafter.

### Example 1

Hereinafter, a method for fabricating a hydrophilic aluminum surface including nano-protrusion structures of a plate shape formed thereon according to a method for fabricating a hydrophilic aluminum surface will be described with reference to FIG. 1.

A surface of aluminum was activated by performing a plasma doping treatment thereon by using a CF₄ gas as a reactive gas. An aluminum board having 99.9% purity was used, and r.f. PACVD was used for the plasma treatment. The aluminum board was treated 30 seconds under conditions in which etching pressure ranged from 2 Pa to 5 Pa and r.f. power ranged from 100 W to 300 W, to fabricate doped-aluminum in which an F element was doped on a surface thereof.

The doped-aluminum was put in boiling water, maintained for 10 minutes, and taken out of the water to fabricate aluminum having a hydrophilic aluminum surface including nano-patterns.

FIGS. 4 and 5 are electron microscope photographs of the hydrophilic aluminum surface of aluminum fabricated according to Example 1. Referring to FIGS. 4 and 5, it can be seen that nano-patterns including nano-protrusion structures of a plate shape densely formed thereon are formed. Also, it can be seen that the plate shaped nano-structure have a thickness ranging from 10 nm to 100 nm.

FIG. 7 shows results of an XPS component analysis of the nano-protrusion structures of Example 1. Components of the nano-protrusion structures are analyzed as AlO(OH), and it can be seen that an amount of oxygen is relatively large in the nano-structures. It can be seen that the structures are similar to a boehmite structure made of an aluminum oxide material reported in an existing document. [Kloprogge, Journal of colloid and interface science 296 (2006) 572-576]

### Example 2

The surface of aluminum was hydrophilized in the same manner as that of Example 1. However, for the aluminum surface, plasma doping time was varied to 30 seconds, 1 minute, 10 minutes, and 30 minutes.

FIG. 6 shows an electron microscope photograph of the hydrophilic aluminum surface fabricated according to Example 2. It can be seen that the nano-protrusion structures were changed over time; when the treatment time was short, a wide and plate-shaped nano-structures were formed; when over 10 minutes passed, needle-shaped nano-structures, rather than plate-shaped nano-structures, appeared, and when 30 minutes passed, dot-shaped nano-structures were formed.

As can be seen from the results of Example 1 and 2, since the F element was doped on the surface of the doped-aluminum, when it reacts with water, a rapid oxidation occurs, and accordingly, needle-shaped or plate-shaped nano patterns are formed. Whether to form needle-shaped nano-protrusion structures, plate-shaped nano-protrusion structures, and dot-shaped nano-protrusion structures can be controlled by regulating a doping time.

### Example 3

The surface of aluminum was hydrophilized in the same manner as that of Example 1, except that conditions for doping were changed as shown in FIG. 8. Aluminum surfaces of respective samples were treated by differentiating plasma doping time as shown in FIG. 8, and pure water contact angles of the treated samples were measured.

### Comparative Example 1

Aluminum having 99.9% purity used in Example 1 was not subjected to hydrophilic aluminum surface treatment and a contact angle thereof was measured. FIG. 3 shows an electron microscope photograph of the non-treated aluminum according to comparative example 1, in which it can be seen that the aluminum has flat surface without nano-patterns.

### Comparative Example 2

Aluminum was F-doped with a reactive gas to fabricate a doped-aluminum in the same manner as that of Example 1, except that the structure forming step was not performed. A structure and a contact angle of the surface of the surface-activated aluminum were measured.

It was checked that the aluminum surface of comparative example 2 did not have nano-protrusion structures, a pure water contact angle was about 60 degrees, similar to that of the general aluminum surface measured in comparative example 1, and the surface did not have hydrophilicity.

### Comparative Example 3

Aluminum was treated in the same manner as that of Example 1; however, activation step based on doping was not performed and only a structure forming step of putting the aluminum in boiling water was performed to fabricate a sample of comparative example 3. A change in a contact angle of the sample by lapse of time was measured and shown in FIG. 10.

### Experimental Example

### Measurement of Contact Angle in Example and Comparative Example

Hereinafter, a method for measuring hydrophilic characteristics of the fabricated surface bodies and results thereof will be described.

Contact angles were measured by using Goniometer (Data Physics instrument Gmbh, OCA 20 L). The equipment is able to measure an optical image and a contact angle of sessile droplet on the surface. A static contact angle was measured by gently landing a 5 ml droplet on the surface.

1) Measurement of Pure Water Contact Angle in Comparative Example 1 and Example 1

FIG. 2 is a photograph of a contact angle on a general aluminum surface (comparative example 1) which was not undergone a hydrophilic aluminum surface treatment (top), and a photograph of a contact angle on an aluminum surface (Example 1) which was undergone a hydrophilic aluminum surface treatment according to the present invention (bottom). Referring to the photographs of FIG. 2, the contact angle of the comparative example 1 was measured as about 60 degrees, while the contact angle of Example 1 was measured as about 12 degrees, confirming that aluminum was treated to have hydrophilic surface.

2) Fabrication of Aluminum Surface Structures of Comparative Example 1 and Example 3 According to Voltage of Plasma Treatment and Measurement of a Pure Water Contact Angle

FIG. 8 is a graph showing a pure water contact angles measured on an aluminum surface by using Example 3 in which the structure forming step was performed, after undergoing an activation step through a plasma treatment under the same conditions as those of Example 1 except for pressures and voltages. Referring to FIG. 8, it can be seen that contact angles were minutely changed over pressure and voltage during a plasma treatment, but super-hydrophilic surfaces having contact angles less than about 10 degrees were formed according to the results of experiment conducted six times by changing pressure and voltage in Example 3. Also, it can be seen that in spite of the changes in the contact angles over the plasma duration time, super-hydrophilicity of less than about 10 degrees were obtained in all the experiment conducted six times.

In comparison to a smooth aluminum surface without nano-patterns having a measured contact angle of about 60 degrees, the results show that all the surfaces of embodiments including nano-patterns were super-hydrophilic surfaces having a contact angle of 10 degrees or less, regardless of etching pressure, voltage, and an activation treatment time.

3) Evaluation of Aging Effect

FIGS. 9 and 10 are graphs showing a change in a pure water contact angle over time by keeping a hydrophilic aluminum surface in the air.

In FIG. 9, ▪ indicates results of a measurement of a change in a contact angle of non-treated aluminum according to comparative example 1, and indicates results of a measurement of a change in a contact angle of hydrophilic aluminum treated according to Example 1 over time. Referring to FIG. 9, it can be seen that the hydrophilic aluminum surface of Example 1 kept in the air had a contact angle less than 10 degrees maintained for 60 days. In comparison, the non-treated aluminum surface of comparative example 1 maintained a contact angle of about 70 degrees, exhibiting hydrophobic characteristics.

Also, in FIG. 10, indicates results of a measurement of a change in a pure water contact angle by using an aluminum surface of comparative example 3 treated only with boiling water without an activation treatment, as a sample, and ▪ indicates results of a change in a contact angle of hydrophilic aluminum treated according to an example of the present invention over time. In the case of the sample of comparative example 3, left in the air, a pure water contact angle started to be increased from seven days after, and after about 30 days had lapsed, a contact angle of about 70 degrees, the same as that of non-treated aluminum, appeared. However, ▪ indicating the results of the example of the present invention in which the contact angle was rarely changed, confirming that the aluminum surface fabricated according to the present invention maintained hydrophilicity without an aging effect.

Such results show that the aluminum surface treated according to the present invention was treated to have excellent hydrophilicity, the treated surface has excellent durability, and no aging effect appeared.

The foregoing examples and advantages are merely exemplary and are not to be considered as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary examples described herein may be combined in various ways to obtain additional and/or alternative exemplary examples.

As the present features may be embodied in several forms without departing from the characteristics thereof, it should also be understood that the above-described examples are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds are therefore intended to be embraced by the appended claims.

What is claimed is:

1. A method for fabricating a hydrophilic aluminum surface, the method comprising the steps of:
an activation step of preparing doped aluminum having an activated surface through doping treatment on a part or whole of an aluminum surface with applying reactive gas thereto; and
a structure forming step of preparing a hydrophilic aluminum surface through oxidizing treatment on the doped aluminum to have nano-patterns comprising nano-protrusion structures on the aluminum surface.

2. The method of claim 1, wherein the doping treatment is performed through an atmospheric plasma treatment method, a plasma chemical vapor deposition method, an ion beam deposition method, a plasma immersion ion implantation method, or a sputter process.

3. The method of claim 1, wherein the doped aluminum is doped with one element selected from the group consisting of fluorine (F), chlorine (Cl), and a combination thereof.

4. The method of claim 1, wherein the reactive gas comprises any one selected from the group consisting of CHF₃, C₂F₆, C₂Cl₂F₄, C₃F₈, C₄F₈, SF₆, and combinations thereof.

5. The method of claim 1, wherein the doping treatment is performed under the conditions in which pressure ranges from 2 Pa to 10 Pa and power ranges from 100 W to 300 W.

6. The method of claim 1, wherein the doping treatment is performed by a plasma-assisted chemical vapor deposition (PACVD) using radio frequency (RF) power.

7. The method of claim 1, wherein the oxidization of the structure forming step is performed by contacting the activated surface of the doped aluminum with a reaction solution comprising water or steam thereof.

8. The method of claim 7, wherein a temperature of the reaction solution ranges from 70° C. to 90° C.

9. The method of claim 1, wherein the nano-protrusion structures comprise needle-shaped, plate-shaped, or dot-shaped nano-protrusions; and nano-protrusions of the nano-protrusion structures contain any one selected from the group consisting of boehmite [AlO(OH)], aluminum oxide (Al₂O₃), and a combination thereof.

10. The method of claim 1, wherein the hydrophilic aluminum surface has super-hydrophilicity in which a pure water contact angle is equal to or less than 10 degrees.

11. An hydrophilic aluminum surface body comprising nano-patterns having nano-protrusion structures formed on a part or whole of an aluminum surface,
wherein the nano-protrusion structures comprise needle-shaped, plate-shaped, or dot-shaped nano-protrusions,
the needle-shaped or plate-shaped nano-protrusions have a height ranging from 10 nm to 100 nm, and
the nano-protrusions contain any one selected from the group consisting of boehmite [AlO(OH)], aluminum oxide (Al₂O₃), and a combination thereof.

12. The hydrophilic aluminum surface body of claim 11, wherein the hydrophilic aluminum surface has super-hydrophilicity in which a pure water contact angle is equal to or less than 10 degrees.

13. A dehumidifier comprising the hydrophilic aluminum surface body according to claim 11.

14. A water collector comprising the hydrophilic aluminum surface body according to claim 11.
